(19) United States
(12) Patent Application Publication
(10) Pub. No.: US 2024/0128963 A1
(43) Pub. Date: Apr. 18, 2024

(54) PROTECTION SYSTEM FOR GATE DRIVERS

(71) Applicants: Navindra Navaratnam, Portland, OR (US); Seh Leong Goh, Sungai Ara (MY)

(72) Inventors: Navindra Navaratnam, Portland, OR (US); Seh Leong Goh, Sungai Ara (MY)

(21) Appl. No.: 18/398,966

(22) Filed: Dec. 28, 2023

(51) Int. Cl. H03K 17/081

(52) U.S. Cl. CPC H03K 17/08104

(57) ABSTRACT

Systems or methods of the present disclosure may provide protection to gate-driving circuitry from anomalous electrical conditions. A method may include detecting an anomalous electrical condition at an input/output (I/O) terminal of an electrical component. The method may also include determining whether the anomalous electrical condition comprises an undershoot condition or an overshoot condition. Additionally, the method may include generating a bias voltage based on the determination that the anomalous electrical condition comprises the undershoot condition or the overshoot condition and applying the bias voltage to the I/O terminal of the electrical component.

### BACKGROUND

The present disclosure relates generally to integrated circuit devices. More particularly, the present disclosure relates to protecting gate drivers from being exposed to overstress.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Thin-gate devices (e.g., drivers) may provide input for gates of transistors of electronic devices such as those used in field-programmable gate arrays (FPGAs), insulated-gate bipolar transistors (IGBTs), metal-oxide-semiconductor field-effect transistors (MOSFETs), and the like. Thin-gate devices may be chosen over alternatives based on speed, channel length, output resistance, manufacturing considerations, or other characteristics. However, components of thin-gate devices (e.g., transistors) may be more vulnerable to electrical overstress during anomalous electrical conditions, such as overshoot or undershoot events, than devices with thicker gates may be. Thus, techniques to efficiently protect thin-gate devices from anomalous electrical conditions may be desired.

### BRIEF DESCRIPTION OF THE DRAWINGS

Various aspects of this disclosure may be better understood upon reading the following detailed description and upon reference to the drawings in which:

FIG. 1 is a schematic diagram of receiver circuitry of a gate driver, in accordance with an embodiment of the present disclosure;

FIG. 2 is schematic diagram of passive undershoot and overshoot mitigation circuitry, in accordance with an embodiment of the present disclosure;

FIG. 3 is a schematic diagram of transmit circuitry of a gate driver that may be protected by the passive undershoot and overshoot mitigation circuitry of FIG. 2, in accordance with an embodiment of the present disclosure;

FIG. 4 is a schematic diagram of receiver circuitry of a gate driver that may be protected by the undershoot and overshoot mitigation circuitry of FIG. 2 may be implemented with, in accordance with an embodiment of the present disclosure;

FIG. 5 is a schematic diagram of active undershoot and overshoot mitigation circuitry, in accordance with an embodiment of the present disclosure; and

FIG. 6 is a flow diagram of a method for mitigating an undershoot or overshoot condition using the active undershoot and overshoot mitigation circuitry of FIG. 5, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

A gate driver, such as a thin-gate driver, may accept an input (e.g., a low-power input) from, for example, a controller, and may produce a drive input (e.g., high-current input) for the gate of an electronic device. As discussed above, thin-gate devices and components may be vulnerable to anomalous electrical conditions. For example, a thin-gate device may include one or more transistors, and an overshoot event or undershoot event may cause electrical overstress to the one or more transistors. Additionally, overshoot or undershoot events may cause a thin-gate driver to produce an unintended drive input, which may impact a connected electrical device, such as an FPGA. As described herein, an overshoot event may include a voltage input (e.g., pad input) greater than a specified range of voltage inputs for the thin-gate driver (e.g., greater than 1.8 Volts), and an undershoot event may include a voltage input lesser than the specified range of voltage inputs (e.g., less than −0.3 Volts).

The present systems and techniques relate to embodiments for efficiently protecting gate-driving circuitry and connected gate-driven devices against anomalous electrical conditions. In particular, embodiments of the present disclosure may include a passive overshoot and undershoot detection system that may detect an overshoot or undershoot condition and may, in response, generate and apply a bias voltage to one or more electrical components of gate-driving circuitry. Embodiments of the present disclosure may alternatively or additionally include an active overshoot and undershoot detection system that may monitor an input/output (I/O) voltage for an overshoot or undershoot condition and may apply a bias voltage based on one or more parameters. In particular, the one or more parameters input to the active overshoot and undershoot detection system may indicate a yanking mode or a termination mode, and the bias voltage may be applied based in part on an indication of the yanking mode or the termination mode. The bias voltage, when applied, may at least partially mitigate an undershoot condition or overshoot condition at an I/O terminal/pad of an electronic device.

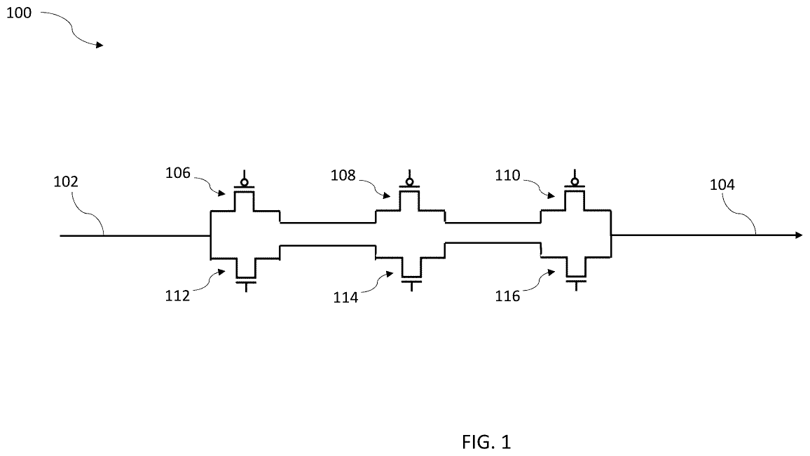

With the foregoing in mind, FIG. 1 is a schematic diagram of receiver buffer circuitry 100 that may be part of and/or electrically coupled between an electrical component, such as an FPGA, and receiver circuitry. For example, a pad terminal 102 may electrically couple the receiver buffer circuitry 100 to an output or input of an FPGA, and an output terminal 104 may electrically couple the receiver buffer circuitry 100 to further electrical circuitry. The buffer circuitry 100 may include one or more transistors, here illustrated as p-channel metal oxide semiconductor (PMOS) transistors 106, 108, and 110 and n-channel metal oxide semiconductor (NMOS) transistors 112, 114, and 116.

The one or more transistors of the receiver buffer circuitry 100 may electrically isolate the pad terminal 102 from the output terminal 104, and may thus electrically isolate the pad terminal 102 from circuitry coupled to the output terminal 104. As illustrated, each of the PMOS transistors 106, 108, and 110 and the NMOS transistors 112, 114, and 116 may include a source terminal, a drain terminal, and a gate terminal having operational characteristics that determine safe (e.g., non-damaging) electrical quantities that may be applied to each terminal. The operational characteristics may, for example, define threshold voltage differences between respective gate terminals and drain terminals that, when exceeded, may cause electrical overstress (EOS), such as thermal damage, to the transistors. It may thus be advantageous to ensure that voltages and/or differences between voltages applied to the source terminals, drain terminals, and gate terminals of the transistors do not exceed associated operational characteristics when, for example, the buffer circuitry 100 experiences anomalous electrical conditions. In particular, as will be described in more detail below, generating and applying a bias voltage to respective gate terminals may allow each transistor of the PMOS transistors 106, 108, and 110 and the NMOS transistors 112, 114, and 116 to remain within operational voltage difference thresholds during undershoot and overshoot events of the buffer circuitry 100.

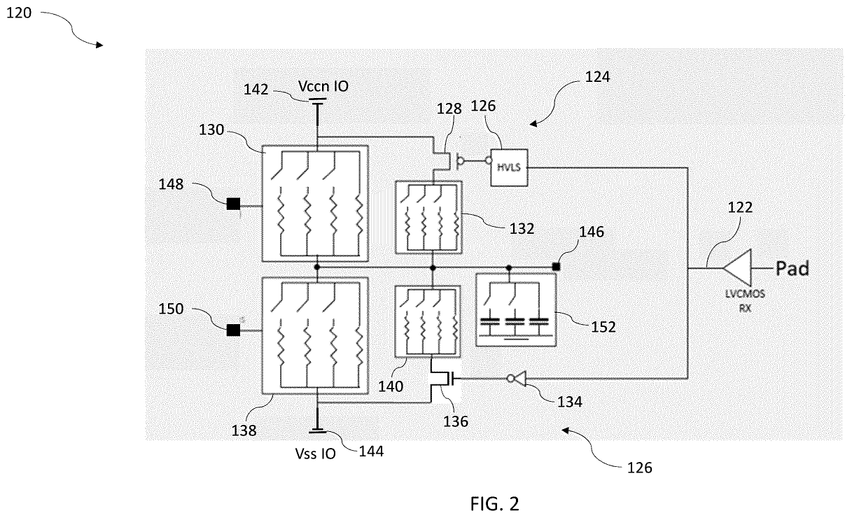

FIG. 2 is schematic diagram of passive overshoot and undershoot mitigation circuitry 120 that may be implemented with the receiver buffer circuitry 100 of FIG. 1. The illustrated passive overshoot and undershoot mitigation circuitry 120 may detect an overshoot or undershoot event and may generate and apply a bias voltage to one or more components and/or circuitry. For example, the passive overshoot and undershoot mitigation circuitry 120 may detect an overshoot event at the pad terminal 102 of the receiver buffer circuitry 100 and may generate and apply a voltage to the one or more transistors of the receiver buffer circuitry 100 such that the transistors remain within operational voltage difference thresholds.

The passive overshoot and undershoot mitigation circuitry 120 may be electrically coupled to a pad terminal 122 of an electronic device, here illustrated as a low voltage complementary metal oxide semiconductor receiver (LVCMOS Rx). The pad terminal 122 may be electrically coupled to overshoot bias generation circuitry 124 and undershoot bias generation circuitry 127. The overshoot bias generation circuitry 124 may include, for example, a high-voltage level shifter (HVLS) 126 and a gate of a PMOS transistor 128 connected in series, with the pad terminal 122 acting as a gating input to the PMOS transistor 128. A source terminal of the PMOS transistor 128 may be connected to Vccn IO voltage 142 and primary resistor ladder circuitry 130. A drain terminal of the PMOS transistor 128 may be connected to secondary resistor ladder circuitry 132. The undershoot bias generation circuitry may include an inverter 134 connected to a gate of a NMOS transistor 136. Further, a source terminal of the NMOS transistor 136 may be connected to a Vss IO voltage 144 and primary resistor ladder circuitry 138, and a drain terminal of the NMOS transistor 136 may be connected to a secondary resistor ladder circuitry 140.

The primary resistor ladder circuitries 130, 138 and the secondary resistor ladder circuitries 132, 140 may each be connected to a bias terminal 146. The primary resistor ladder circuitries 130, 138 and the secondary resistor ladder circuitries 132, 140 may be selectively connected (e.g., closed) or disconnected (e.g., opened) to the pad via the PMOS transistor 128 and the NMOS transistor 136 to alter a bias voltage at the bias terminal 146.

The selectable connection and disconnection of the secondary resistor ladder circuitries 132 and 140 (via the PMOS transistor 128 and the NMOS transistor 1360) may create a selectable voltage drop between the source voltages and the bias terminal 146. During anomalous conditions, such as those in which the pad terminal 122 is undergoing an undershoot or overshoot event, the secondary resistor ladder circuitries 132 or 140 may be selectively connected between the bias terminal 146 and a respective source. For example, during an overshoot event at the pad terminal 122, the voltage at the pad terminal 122 may rise from a low value to a high value. As a result, the inverter 134 may cause a voltage at the gate terminal of the NMOS transistor 136 to fall from a high value to a low value that causes a disconnection between the Vss IO voltage 144 and the secondary resistor ladder circuitry 140. As such, during an overshoot event, the Vss IO voltage 144 may remain only connected to the bias terminal 146 via the primary resistor ladder circuitry 138.

Additionally, when the voltage at the pad terminal 122 rises from a high to low value during an overshoot event, the HVLS 126 may cause the voltage at the gate terminal of the PMOS transistor 128 to fall from a high value to a low value. As a result, the source terminal and drain terminal of the PMOS transistor 128 may form a connection, allowing a connection between the Vccn IO voltage 142 and the bias terminal 146 via the secondary resistor ladder circuitry 132. As such, the Vccn IO voltage 142 may be connected to the bias terminal 146 via both the primary resistor ladder circuitry 130 and the secondary resistor ladder circuitry 132. This new parallel resistance of the secondary resistor ladder circuitry 132 and the primary resistor ladder circuitry 130 between the Vccn IO voltage 142 and the bias terminal 146 may cause an alteration (e.g., reduction) of the bias voltage at the bias terminal 146, and this altered voltage may be applied to, for example, transistors of receiver buffer circuitry during an overshoot event at the pad terminal 122, as described herein.

The primary resistor ladder 130 may include a bias midpoint terminal 148 with a voltage that may be altered by, for example, the connection and disconnection of the secondary resistor ladder circuitry 132 and that may be applied to electronic components during anomalous conditions. The bias midpoint terminal 148 may have a voltage that is different than the voltage of the bias terminal 146 The bias midpoint terminal 148 may thus be applied to different components based on operational characteristics of the components (e.g., energy dissipation properties) or a desired voltage difference between terminals of a component. In an example, during an overshoot event in which the secondary resistor ladder circuitry 132 is connected, the voltage of the bias midpoint terminal 148 may be lower than (e.g., half of) the voltage of the bias terminal 146.

During an undershoot event at the pad terminal 122, the voltage of the pad terminal 122 may fall from a high value to a low value. In response, the HVLS 126 may cause the voltage at the gate terminal of the PMOS transistor 128 to rise from a low value to a high value, which may disconnect the Vccn IO voltage 142 from the secondary resistor ladder circuitry 132. As such, during an undershoot event, the Vccn IO voltage 142 may only be connected to the bias terminal 146 via the primary resistor ladder circuitry 130.

The voltage of the pad terminal 122 falling from a high value to a low value, as a result of the inversion by inverter 134, may also cause the voltage at the gate terminal of the NMOS transistor 136 to rise from a low value to a high value. As a result, the Vss IO voltage 144 and the secondary resistor ladder circuitry 140 are connected via the NMOS transistor 136. As a result, the bias terminal 146 may be connected to the Vss IO voltage 144 via both the primary resistor ladder circuitry 138 and the secondary resistor ladder circuitry 140. As may be appreciated, the resulting parallel resistance of the secondary resistor ladder circuitry 140 and the primary resistor ladder circuitry 138 between the Vss IO voltage 144 and the bias terminal 146 may cause an alteration of the bias voltage at the bias terminal 146, and this altered bias voltage may be applied to, for example, transistors of receiver buffer circuitry during an undershoot event at the pad terminal 122. Additionally, the primary resistor ladder circuitry 138 may include a bias midpoint terminal 150, and the bias midpoint terminal 150 may have a voltage that is different than the voltage of the bias terminal 146. During an undershoot event, the voltage at the bias midpoint terminal 150 may be lower than the voltage at the bias terminal 146 and may thus be applied differently in response to the undershoot event.

In some embodiments, the overshoot and undershoot mitigation circuitry 120 may also include an RC filter 152 coupled to the bias terminal 146. The RC filter 152 may be programmable and may further alter (e.g., dampen) the bias voltage or a rate of change of the bias voltage of the bias terminal 146. For example, the RC filter 152 may allow kickback during an anomalous undershoot or overshoot condition, which may account for a delay between a change in the voltage of the pad terminal 122 and a resulting change in the bias voltage of the bias terminal 146 (e.g., as caused by the overshoot bias generation circuitry 124 and/or undershoot bias generation circuitry 127).

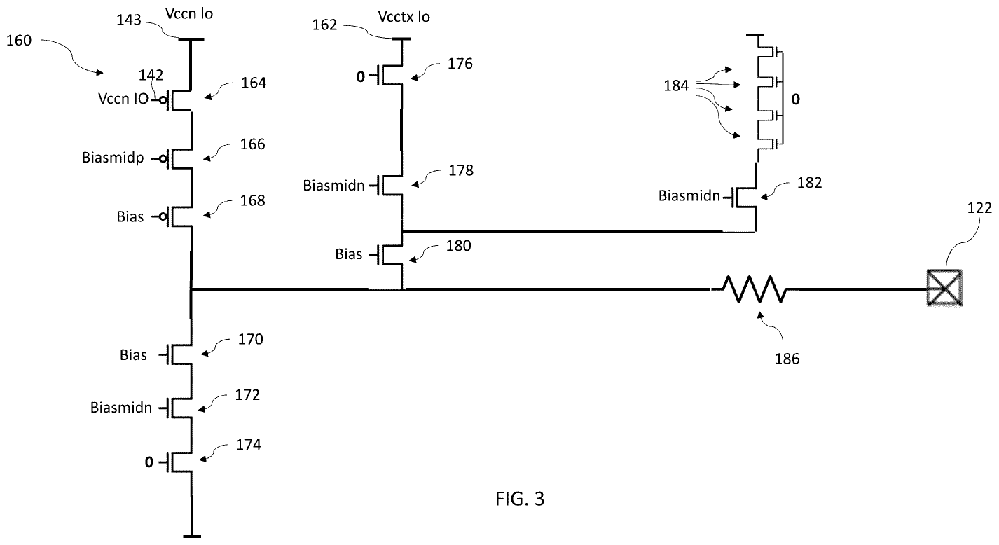

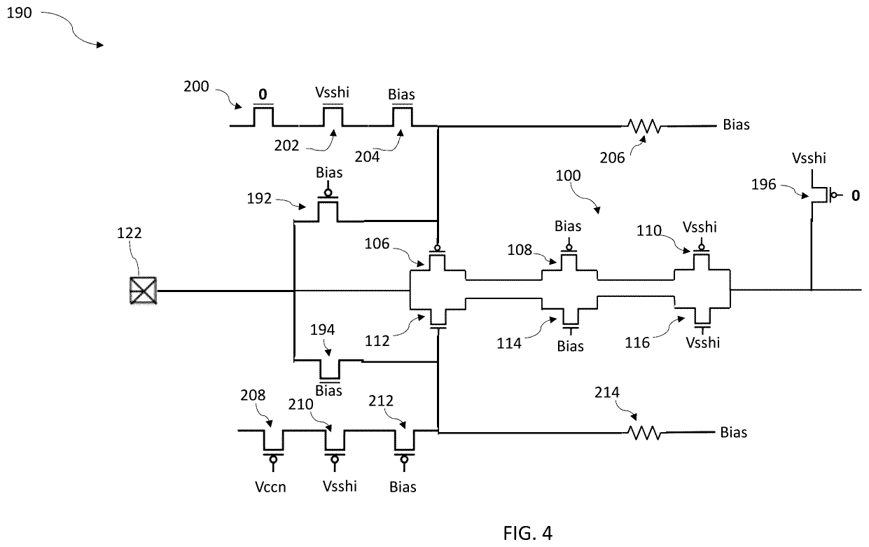

FIGS. 3-4 illustrate examples of circuitry to which voltages generated by the overshoot and undershoot mitigation circuitry 120 may be applied and may be discussed with reference to FIG. 2. FIG. 3 illustrates a schematic diagram of transmit circuitry 160 that may be used as part of or in conjunction with an FPGA or other suitable gate-driven circuitry. The transmit circuitry may include the pad terminal 122, PMOS transistors 164, 166, and 168, NMOS transistors 170, 172, 174, 176, 178, 180, and 182, and resistor 186. The transmit circuitry 160 may also include several input voltages, including a Vccn lo voltage 143 applied to a source terminal of the PMOS transistor 164, Vcctx lo voltage 162 applied to a source terminal of the NMOS transistor 176, and Vccn hi voltage applied to a gate terminal of the NMOS transistor 176.

In addition, voltages generated by, for example, the passive overshoot and undershoot mitigation circuitry 120 may be applied at gating terminals of transistors of the transmit circuitry 160. The voltages generated by the passive overshoot and undershoot mitigation circuitry 120 may be applied to the transmit circuitry 160 such that the operational limits (e.g., thresholds) of the transistors of the transmit circuitry 160 are not exceeded when anomalous condition are present at the pad terminal 122. It should be noted that while one example of an application of such voltages is illustrated in FIG. 3, other embodiments are envisioned that may include the application certain bias voltages at different transistors. In the illustrated example, the Vccn IO voltage 142 is applied to a gate terminal of the PMOS transistor 164, a Biasmidp voltage generated at the bias midpoint terminal 148 is applied to a gate terminal of the PMOS transistor 166, and a bias voltage generated at the bias terminal 146 is applied to respective gate terminals of the PMOS transistor 168 and the NMOS transistors 170 and 180. Further, a Biasmidn voltage generated at the bias midpoint terminal 150 may be applied to respective gate terminals of the NMOS transistors 172, 178, and 182, and a zero voltage or ground may be applied to respective gate terminals of the NMOS transistors 174, 176, and 184.

As discussed with reference to FIG. 2, a change in the voltage of the pad terminal 122 may cause a change in the voltages generated by the passive overshoot and undershoot mitigation circuitry 120 and, thus, may cause a change in the voltages applied to the gate terminals of the illustrated transistors. For example, if an overshoot event is present at the pad terminal 122, the passive overshoot and undershoot mitigation circuitry 120 may, in response, generate voltages (e.g., at the bias terminal 146 and the bias midpoint terminals 148 and 150) based on the overshoot condition, and the voltages may be applied to gate terminals of the transistors such that voltage differences between terminals of the transistors do not exceed a threshold, at least partially mitigating overstress to the transistors. Likewise, if an undershoot condition is present at the pad terminal 122, the passive overshoot and undershoot mitigation circuitry 120 may, in response, generate voltages based on the undershoot condition, and the voltages may be applied similarly. In an example, the voltages generated by the passive overshoot and undershoot mitigation circuitry 120 in response to an overshoot condition are higher than those generated in response to an undershoot condition. This may lessen voltage differences between the pad terminal 122, an input voltage, and/or transistors in series with pad terminal 122 and the input voltage. In any case, manipulating the voltages at gate terminals of the transistors as such may allow input voltages of the transmit circuitry 160 (e.g., Vccn lo, Vcctx lo, and so on) to remain relatively static, which may be advantageous if, for example, the input voltages are used elsewhere in a system.

FIG. 4 illustrates a schematic diagram of receiver circuitry 190 that may be used as part of or in conjunction with an FPGA or other suitable gate-driven circuitry and may include the receiver buffer circuitry 100 of FIG. 1. In addition to the PMOS transistors 106, 108, and 110 and the NMOS transistors 112, 114, and 116 of the receiver buffer circuitry 100, the receiver circuitry 190 may include the pad terminal 122 coupled to the source terminals of PMOS transistor 106 and the NMOS transistor 112. The receiver circuitry 190 may also include a PMOS transistor 192 coupled between a gate terminal and the source terminal of the PMOS transistor 106, and an NMOS transistor 194 coupled between a gate terminal and source terminal of the NMOS transistor 112. The receiver circuitry 190 may include input voltage Vsshi coupled to the drain terminals of the PMOS transistor 110 and the NMOS transistor 116 via an NMOS transistor 196. Vsshi is also coupled to the gates of the PMOS transistor 110 and the NMOS transistor 116. In addition, the receiver circuitry 190 may include NMOS transistors 200, 202, and 204 coupled together and to a resistor 206. The receiver circuitry 190 also includes PMOS transistors 208, 210, 212 coupled to a resistor 214. The NMOS transistors 200, 202, and 204 and the PMOS transistors 208, 210, and 212 may be used for interfacing with other circuitry. For example, these components may facilitate electrical connection to further circuitry or components with different operational standards (e.g., input voltages and the like). Vsshi may be coupled to the gates of the NMOS transistor 202 and the PMOS transistor 210. The gate of the NMOS transistor 200 may be coupled to ground, and the gate of the PMOS transistor 208 may be coupled to an instance of Vcc (Vccn).

As with the transmit circuitry 160 of FIG. 3, voltages generated by, for example, the passive overshoot and undershoot mitigation circuitry 120 may be applied to terminals of the illustrated to terminals of the illustrated transistors. Application of the generated voltages to the terminals of the transistors may allow voltage differences between the terminals to remain within operational limits of the transistors, which may obviate stress-related damage to the transistors or connected components. In the illustrated example, a bias voltage generated at the bias terminal 146 is applied to a gate terminal of the PMOS transistor 192. Likewise, the bias voltage is applied to the gate terminal of the NMOS transistor 194. The bias voltage is further applied to gate terminals of the PMOS transistor 108 and the NMOS transistor 114 of the receiver buffer circuitry 100 as well as to respective gate terminals of the NMOS transistor 204 and the PMOS transistor 212.

The bias voltage applied to transistors of the receiver circuitry 190 may be generated based on an undershoot or overshoot condition at the pad terminal 122 and may allow the voltage differences between terminals of each transistor to remain within operational thresholds. For example, for instances in which the voltage of the pad terminal increases (e.g., during an overshoot condition), the generated bias voltage may increase likewise. This may, via application of the bias voltage to the gate terminal of the transistor 192, cause a corresponding increase in the voltage applied to the gate terminal of the PMOS transistor 106, thus reducing a voltage difference between the gate terminal and source terminal of the PMOS transistor 106 that may otherwise rise beyond operational voltage difference (Vgs) thresholds during such an overshoot condition. Similarly, during an undershoot condition in which the voltage of the pad terminal 122 decreases, the generated bias voltage may decrease. As such, upon applying the decreased bias voltage to the transistor 192, the decreased bias voltage may be propagated to the gate terminal of the PMOS transistor 106. As such, the voltage of the gate terminal of the transistor 106 may be sufficiently low as to cause the voltage difference between the gate terminal and source terminal (Vgs) of the transistor 106 to not exceed an operational threshold difference.

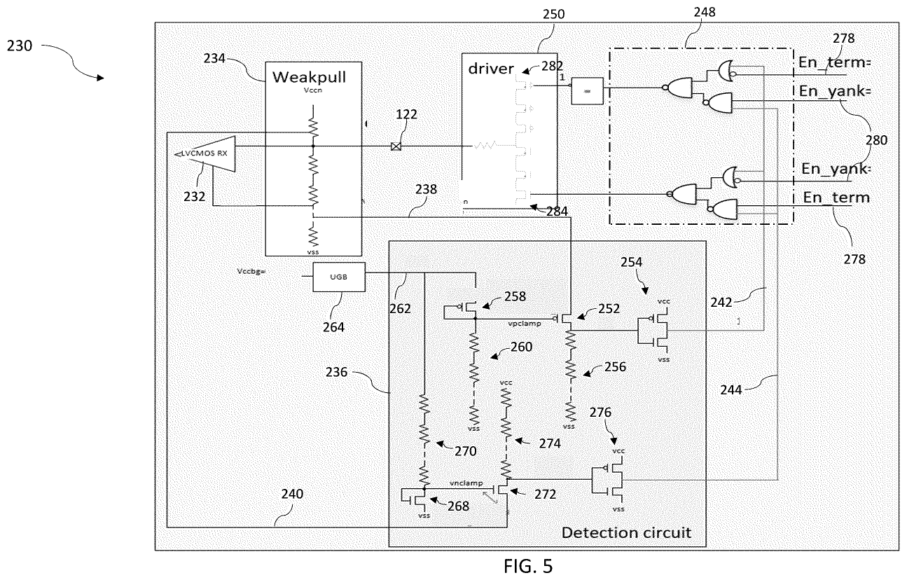

FIG. 5 illustrates a schematic diagram of active undershoot and overshoot mitigation circuitry 230 that may be implemented to detect and mitigate an undershoot or overshoot condition at a terminal. The active undershoot and overshoot mitigation circuitry 230 may include or be coupled to the pad terminal 122, and the pad terminal 122 may be electrically coupled to and/or may be input or output for component of gate-driven circuitry, such as the illustrated low voltage complementary metal oxide semiconductor receiver (LVCMOS Rx) 232. In the illustrated embodiment, a resistor ladder 234 may be coupled between the pad terminal 122 and the LVCMOS 232. Further, the pad terminal 122 may be coupled to a first node 238 and a second node 240 through different points on the resistor ladder 234. The first node 238 and second node 240 may serve as inputs to detection circuitry 236. The pad terminal 122 may also be coupled, via a driver 250, to one or more source voltages. Moreover, the driver 250 may be based on one or more inputs to alter a voltage of the pad terminal 122 to mitigate an undershoot or overshoot event.

The detection circuitry 236 may detect an undershoot event or overshoot event based on voltages at the first node 238 and/or second node 240 and may produce one or more indications at a first detection output 242 and a second detection output 244. The first detection output 242, the second detection output 244, termination inputs 278, and yank inputs 280 may be provided as input to selection circuitry 248. The selection circuitry 248 may, based on the provided inputs, produce selection circuitry outputs that may be provided as inputs to the driver 250. Further, the driver 250 may, based on the selection circuitry outputs, couple the pad terminal 122 to a first driver voltage 282 or a second driver voltage 284. As such, based on the selection circuitry outputs, the driver 250 may alter a voltage at the pad terminal 122 to compensate for potential overshoot or undershoot conditions.

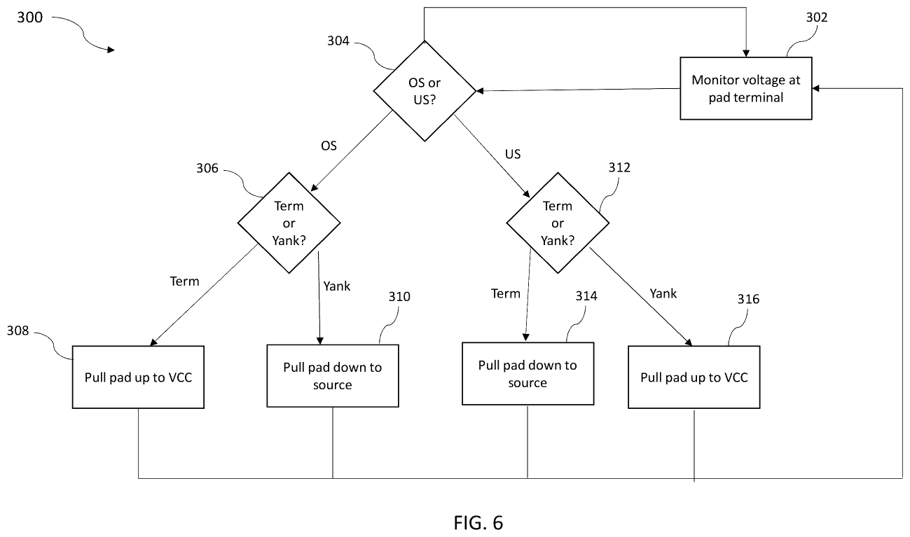

FIG. 6 is a flow chart of a method 300 for mitigating an undershoot or overshoot condition that may be implemented by the undershoot and overshoot mitigation circuitry 230 and will be described with reference to FIG. 5. The method 300 may begin, at block 302, with monitoring a voltage at the pad terminal 122. In particular, a voltage at the first node 238 and second node 240 may be based on a voltage of the pad terminal 122, and a change in the voltage at the pad terminal 122 may cause a change in the voltages of the first node 238 and/or the second node 240. For example, during an overshoot event, the voltage of the pad terminal 122 rises above a threshold value (e.g., 1.8 Volts) and, in response, a voltage at the first node 238 may rise above a corresponding threshold value (e.g., 0.75 Volts). Similarly, during an undershoot event, the voltage of the pad terminal 122 may fall below a threshold value (e.g.,−0.3 Volts) and, in response, a voltage at the second node 240 may fall below a corresponding threshold value (e.g., 0 Volts). As may be appreciated, the threshold values at the pad terminal 122 may indicate the overshoot or undershoot events and may correspond to voltage values that, when exceeded, may cause overstress of components. The threshold values may also depend on tolerance values (e.g., voltage tolerance values) that may define buffers between overshoot events, undershoot events, and normal conditions at the pad terminal 122. In the illustrated embodiment, the undershoot and overshoot mitigation circuitry 230 may be supplied by a voltage source Vccbg via a unity gain buffer (UGB) 264 at a reference node 262. The reference node 262 may be coupled to a source terminal of a PMOS transistor 258. The PMOS transistor 258 may include other terminals coupled together and to a Vss source via a resistance (e.g., set of resistors) 260. The other terminals of the PMOS transistor 258 may also be coupled to a Vpclamp node. In the illustrated embodiment, the Vpclamp node may be a bias voltage based on Vss and the resistance 260. The PMOS transistor 258 may generate a threshold voltage or DC tolerance at the Vpclamp node. The PMOS transistor 252 may also be coupled to Vss through resistance 256. When there is no overshoot (e.g., pad voltage less than 1.8V), Vgs of PMOS transistor 252 is less than the threshold voltage causing the lower terminal of the PMOS transistor 252 to be a logic low if no overshoot has occurred. This voltage is then passed to an inverting level shifter 254 that shifts the logic low to VCC on the first detection output 242 when in normal operation or in undershoot conditions.

Because the voltages at the first node 238 and second node 240 may be based on a voltage at the pad terminal 122, the detection circuitry 236 may, in block 304, detect an overshoot or undershoot condition at the pad terminal 122 based on voltages at the first node 238 and the second node 240. During an overshoot event at the pad terminal 122, for example, the voltage of the first node 238 may exceed a threshold that causes Vgs of the PMOS transistor 252 to exceed the Vt of the PMOS transistor 252. This causes the drain terminal of the PMOS transistor 252 to be a logic high that is level shifted to Vss in the inverting level shifter 254. Thus, the first detection output 242 is a logic low when an overshoot has occurred.

The overshoot and undershoot mitigation circuitry 230 may also detect an undershoot condition at the pad terminal 122 based on a voltage at the second node 240. The reference node 262 may be connected to a Vnclamp node via a resistance 270, and the Vnclamp node may be connected to a drain terminal and a gate terminal of the NMOS transistor 268. Like the Vpclamp node, the Vnclamp node may be a bias voltage based on Vss and the resistance 270. As illustrated, the Vnclamp node may be coupled to a gate terminal of an NMOS transistor 272, and the second node 240 may be coupled to a source terminal of the NMOS transistor 272. A drain terminal of the NMOS transistor 272 may be coupled, via a resistance 274, to a Vcc source. When there is no undershoot has occurred, Vgs is less than the threshold voltage causing the drain of the NMOS transistor 272 to be a logic high. The logic high is inverted in an inverted level shifter 276 to VSS. In other words, the second detection output 244 is a logic low (e.g., Vss). When an undershoot has occurred, the second detection output 244 is a logic high

As mentioned, the first detection output 242 and the second detection output 244 may be provided as inputs to the selection circuitry 248 and may indicate the presence of an overshoot condition or undershoot condition at the pad terminal 122. In addition, the termination inputs 278 and the yank inputs 280 may be provided to the selection circuitry 248 and may indicate a selection of a termination mode or a yanking mode, respectively. The termination inputs 278 and the yank inputs 280 may be provided by, for example, by controller circuitry in communicative connection with the undershoot and overshoot mitigation circuitry 230, such as a soft processor implemented as part of an FPGA connected to the pad terminal 122, a hard processor, or a combination thereof. The termination inputs 278 and the yank inputs 280 may also be configured by a user (e.g., programmer) of a connected FPGA based on operational needs or configurations, for example.

The selection circuitry may, based on the first detection output 242, the second detection output 244, the termination inputs 278, and the yank inputs 280, produce one or more outputs (e.g., logic highs and/or lows) that selectively enable or disable transistors of the driver 250. In particular, the termination and yanking mode may cause the driver 250 to pull the pad terminal 122 to the first driver voltage 282, which may correspond to a voltage near the upper limit of an operational range of voltages of the pad terminal 122, or to the second driver voltage 284, which may correspond to a lower limit of the operational range of voltages of the pad terminal 122. However, if no undershoot or overshoot is detected (e.g., the first detection output 242 is asserted a and the second detection output 244 is deasserted), the selection circuitry 248 may cause the driver 250 to not pull the pad terminal to either of the first driver voltage 282 or the second driver voltage 284.

The termination inputs 278, when asserted and when an overshoot or undershoot event is detected, may cause the selection circuitry 248 to instruct the driver 250 to couple the pad terminal 122 to a driver voltage corresponding to the detected voltage and within a threshold range of operational voltages of the pad terminal 122. For example, in block 306, if an overshoot event is detected and the termination mode is indicated, the selection circuitry 248 may, in block 308, cause the driver 250 to pull the pad terminal 122 to a high voltage within the threshold range of operational voltages (e.g., the first driver voltage 282). The overshoot condition may, for example, indicate that the voltage of the pad terminal 122 exceeds 1.8 Volts, and the first driver voltage 282 may have a value near and/or below 1.8 Volts to gently pull the pad voltage to acceptable levels by dumping excess charge via the driver 250. Likewise, if an undershoot condition is detected in block 304 (e.g., a voltage of the pad terminal is lower than a minimum of operational voltages of the pad terminal 122) and the termination mode is indicated as in block 312, the selection circuitry 248 may cause the driver 250 to pull the pad terminal 122 to a low voltage (e.g., the second driver voltage 284) in block 314 at or above a lower range (e.g., 0 to −0.3V) to gently pull the pad voltage up to acceptable levels by bleeding charge from the source of the second driver voltage 284. In any case, after the termination mode the voltage at the pad terminal 122 in blocks 308 or 314 to acceptable levels, the method 300 may begin again in block 302.

The yanking mode, when an undershoot or overshoot condition is detected, may cause the driver 250 to couple the pad terminal 122 to a driver voltage opposite the detected voltage and within the operational range of voltages of the pad terminal 122. For example, in block 306, if the overshoot condition (e.g., high voltage) is detected and the yanking mode is asserted, the pad terminal 122 may be pulled toward a low voltage (e.g., the second driver voltage 284) in block 310 causing a more rapid change in voltage than the termination mode for overshoot conditions. Likewise, if the undershoot condition (e.g., low voltage) is detected in block 304 and the yanking mode is indicated in block 312, the pad terminal 122 may be pulled toward a high voltage in block 316 causing a more rapid change in voltage than the termination mode for undershoot conditions. After the yanking mode is implemented at the pad terminal in blocks 310 or 316 to pull the voltage at the pad terminal 122 back to acceptable levels, the method 300 may begin again at block 302.

As may be appreciated, when operating in the yanking mode, a larger voltage difference may be present between the pad terminal 122 and a coupled driver voltage (e.g., the first driver voltage or the second driver voltage) than when operating in the termination mode. Thus, the yanking mode may lead to more rapid mitigation of an overshoot or undershoot condition at the pad terminal 122. As such, the yanking mode may be selected, for example, when a more rapid response to anomalous conditions is desired, such as when components coupled to the pad terminal 122 are particularly sensitive to overshoot or undershoot conditions. However, if the voltage correction using the yanking mode occurs for too long, the voltage of the pad terminal 122 may be inverted. For example, a downward yank in response to an overshoot may cause a sign change to a low value while an upward yank in response to an undershoot may cause a sign change to a high value. One mechanism to prevent such logic inversion may be to chop the outputs of the selection circuitry 248 to a duration sufficient to correct overshoot or undershoot without changing the logic values. Additionally or alternatively, more intermediate values may be used to correct voltages more gently but more rapidly than in the termination mode. The termination mode may cause less rapid changes in a voltage of the pad terminal 122 and may thus maintain an intended signal state (e.g., high or low) of the pad terminal 122. The termination mode may be selected, for example, when a component connected to the pad terminal is particularly sensitive to changes in a signal state of the pad terminal.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. A method, comprising:
detecting an anomalous electrical condition at an input/output (I/O) terminal of an electrical component;
determining whether the anomalous electrical condition comprises an undershoot condition or an overshoot condition;
generating a bias voltage based on the determination that the anomalous electrical condition comprises the undershoot condition or the overshoot condition; and
applying the bias voltage to the I/O terminal of the electrical component.

EXAMPLE EMBODIMENT 2. The method of claim 1, wherein the electrical component comprises a field-programmable gate array (FPGA).

EXAMPLE EMBODIMENT 3. The method of claim 1, wherein the electrical component comprises a transistor of a gate driver of an FPGA.

EXAMPLE EMBODIMENT 4. The method of claim 1, wherein determining whether the anomalous electrical condition comprises an undershoot condition or an overshoot condition comprises comparing a voltage of the I/O terminal to a reference voltage.

EXAMPLE EMBODIMENT 5. The method of claim 1, wherein the bias voltage is generated based on a first resistance and a second resistance, the first resistance coupling a bias terminal and a first source, and the second resistance coupling the bias terminal and a second source.

EXAMPLE EMBODIMENT 6. The method of claim 5, comprising:
changing the first resistance in response to determining that the anomalous electrical condition comprises the undershoot condition; and
changing the second resistance in response to determining that the anomalous electrical condition comprises the overshoot condition.

EXAMPLE EMBODIMENT 7. The method of claim 5, wherein the first resistance comprises first primary resistor ladder circuitry and first secondary resistor ladder circuitry, and wherein the second resistance comprises second primary resistor ladder circuitry and second secondary resistor ladder circuitry.

EXAMPLE EMBODIMENT 8. The method of claim 1, wherein the bias voltage is generated based on one or more selection inputs.

EXAMPLE EMBODIMENT 9. The method of claim 8, wherein the one or more selection inputs comprise one or more termination inputs and one or more yank inputs, and comprising:
generating a first bias voltage when the one or more yank inputs are asserted;
generating a second bias voltage when the one or more termination inputs are asserted; and
applying the first bias voltage or the second bias voltage to the I/O terminal of the electrical component.

EXAMPLE EMBODIMENT 10. The method of claim 9, wherein a first voltage difference between the first bias voltage and a voltage of the I/O terminal is greater than a second voltage difference between the second bias voltage and the voltage of the I/O terminal.

EXAMPLE EMBODIMENT 11. A system, comprising:
detection circuitry configured to:
generate a first detection output based on a first voltage of a first node, wherein the first detection output is indicative of whether an overshoot condition is present at an I/O terminal;
generate a second detection output based on a second voltage of a second node, wherein the second detection output is indicative of whether an undershoot condition is present at the I/O terminal;
selection circuitry coupled to the detection circuitry and configured to:
determine one or more driver inputs based on the first detection output, the second detection output, and one or more selection inputs; and
provide the one or more driver inputs to driver circuitry;
the driver circuitry configured to:
receive the one or more driver inputs;
generate a bias voltage based on the one or more driver inputs; and
apply the bias voltage to the I/O terminal.

EXAMPLE EMBODIMENT 12. The system of claim 11, wherein the overshoot condition comprises a voltage of the I/O terminal being above a range of operational voltages of the I/O terminal, and wherein the undershoot condition comprises the voltage of the I/O terminal being below the range of operational voltages of the I/O terminal.

EXAMPLE EMBODIMENT 13. The system of claim 11, wherein the one or more selection inputs are indicative of a termination mode or a yanking mode.

EXAMPLE EMBODIMENT 14. The system of claim 13, wherein the selection circuitry is configured to:
determine a first driver input of the one or more driver inputs in response to:
the first detection output being indicative of the overshoot condition and the one or more selection inputs being indicative of the termination mode; or
the second detection output being indicative of the undershoot condition and the one or more selection inputs being indicative of the yanking mode; and
determine a second driver input of the one or more driver inputs in response to:
the first detection output being indicative of the overshoot condition and the one or more selection inputs being indicative of the yanking mode; or
the second detection output being indicative of the undershoot condition and the one or more selection inputs being indicative of the termination mode.

EXAMPLE EMBODIMENT 15. The system of claim 14, wherein the driver circuitry is configured to:
generate the bias voltage comprising a first bias voltage value in response to the one or more driver inputs comprising the first driver input; and
generate the bias voltage comprising a second bias voltage value in response to the one or more driver inputs comprising the second driver input, wherein the first bias voltage value is greater than the second bias voltage value.

EXAMPLE EMBODIMENT 16. A system, comprising:
one or more primary resistor ladder circuitries coupled between one or more sources and a bias terminal;
a first transistor comprising a first gate input coupled to an I/O terminal of an electrical component, the first transistor configured to selectively couple first secondary resistor ladder circuitry between a first source of the one or more sources and the bias terminal in response to a voltage of the I/O terminal being above a voltage range; and
a second transistor comprising a second gate input coupled to the I/O terminal of the electrical component, the second transistor configured to selectively couple second secondary resistor ladder circuitry between a second source of the one or more sources and the bias terminal in response to the voltage of the I/O terminal being below the voltage range.

EXAMPLE EMBODIMENT 17. The system of claim 16, wherein the bias terminal is configured to apply a bias voltage to one or more transistors of gate-driving circuitry.

EXAMPLE EMBODIMENT 18. The system of claim 16, wherein a bias voltage of the bias terminal is based on a first resistance of the one or more primary resistor ladder circuitries, a second resistance of the first secondary resistor ladder circuitry, and a voltage value of the first source in response to the voltage of the I/O terminal being above the voltage range.

EXAMPLE EMBODIMENT 19. The system of claim 16, wherein a bias voltage of the bias terminal is based on a first resistance of the one or more primary resistor ladder circuitries, a third resistance of the second secondary resistor ladder circuitry, and a voltage value of the second source in response to the voltage of the I/O terminal being below the voltage range.

EXAMPLE EMBODIMENT 20. The system of claim 16, wherein the voltage range is between −0.3 volts and 1.8 volts.

What is claimed is:

1. A method, comprising:
detecting an anomalous electrical condition at an input/output (I/O) terminal of an electrical component;
determining whether the anomalous electrical condition comprises an undershoot condition or an overshoot condition;
generating a bias voltage based on the determination that the anomalous electrical condition comprises the undershoot condition or the overshoot condition; and
applying the bias voltage to the I/O terminal of the electrical component.

2. The method of claim 1, wherein the electrical component comprises a field-programmable gate array (FPGA).

3. The method of claim 1, wherein the electrical component comprises a transistor of a gate driver of an FPGA.

4. The method of claim 1, wherein determining whether the anomalous electrical condition comprises an undershoot condition or an overshoot condition comprises comparing a voltage of the I/O terminal to a reference voltage.

5. The method of claim 1, wherein the bias voltage is generated based on a first resistance and a second resistance, the first resistance coupling a bias terminal and a first source, and the second resistance coupling the bias terminal and a second source.

6. The method of claim 5, comprising:
changing the first resistance in response to determining that the anomalous electrical condition comprises the undershoot condition; and
changing the second resistance in response to determining that the anomalous electrical condition comprises the overshoot condition.

7. The method of claim 5, wherein the first resistance comprises first primary resistor ladder circuitry and first secondary resistor ladder circuitry, and wherein the second resistance comprises second primary resistor ladder circuitry and second secondary resistor ladder circuitry.

8. The method of claim 1, wherein the bias voltage is generated based on one or more selection inputs.

9. The method of claim 8, wherein the one or more selection inputs comprise one or more termination inputs and one or more yank inputs, and comprising:
generating a first bias voltage when the one or more yank inputs are asserted;
generating a second bias voltage when the one or more termination inputs are asserted; and
applying the first bias voltage or the second bias voltage to the I/O terminal of the electrical component.

10. The method of claim 9, wherein a first voltage difference between the first bias voltage and a voltage of the I/O terminal is greater than a second voltage difference between the second bias voltage and the voltage of the I/O terminal.

11. A system, comprising:
detection circuitry configured to:
generate a first detection output based on a first voltage of a first node, wherein the first detection output is indicative of whether an overshoot condition is present at an I/O terminal;
generate a second detection output based on a second voltage of a second node, wherein the second detection output is indicative of whether an undershoot condition is present at the I/O terminal;
selection circuitry coupled to the detection circuitry and configured to:
determine one or more driver inputs based on the first detection output, the second detection output, and one or more selection inputs; and
provide the one or more driver inputs to driver circuitry;
the driver circuitry configured to:
receive the one or more driver inputs;
generate a bias voltage based on the one or more driver inputs; and
apply the bias voltage to the I/O terminal.

12. The system of claim 11, wherein the overshoot condition comprises a voltage of the I/O terminal being above a range of operational voltages of the I/O terminal, and wherein the undershoot condition comprises the voltage of the I/O terminal being below the range of operational voltages of the I/O terminal.

13. The system of claim 11, wherein the one or more selection inputs are indicative of a termination mode or a yanking mode.

14. The system of claim 13, wherein the selection circuitry is configured to:
determine a first driver input of the one or more driver inputs in response to:
the first detection output being indicative of the overshoot condition and the one or more selection inputs being indicative of the termination mode; or
the second detection output being indicative of the undershoot condition and the one or more selection inputs being indicative of the yanking mode; and
determine a second driver input of the one or more driver inputs in response to:
the first detection output being indicative of the overshoot condition and the one or more selection inputs being indicative of the yanking mode; or
the second detection output being indicative of the undershoot condition and the one or more selection inputs being indicative of the termination mode.

15. The system of claim 14, wherein the driver circuitry is configured to:
generate the bias voltage comprising a first bias voltage value in response to the one or more driver inputs comprising the first driver input; and
generate the bias voltage comprising a second bias voltage value in response to the one or more driver inputs comprising the second driver input, wherein the first bias voltage value is greater than the second bias voltage value.

16. A system, comprising:
one or more primary resistor ladder circuitries coupled between one or more sources and a bias terminal;
a first transistor comprising a first gate input coupled to an I/O terminal of an electrical component, the first transistor configured to selectively couple first secondary resistor ladder circuitry between a first source of the one or more sources and the bias terminal in response to a voltage of the I/O terminal being above a voltage range; and
a second transistor comprising a second gate input coupled to the I/O terminal of the electrical component, the second transistor configured to selectively couple second secondary resistor ladder circuitry between a second source of the one or more sources and the bias terminal in response to the voltage of the I/O terminal being below the voltage range.

17. The system of claim 16, wherein the bias terminal is configured to apply a bias voltage to one or more transistors of gate-driving circuitry.

18. The system of claim 16, wherein a bias voltage of the bias terminal is based on a first resistance of the one or more primary resistor ladder circuitries, a second resistance of the first secondary resistor ladder circuitry, and a voltage value of the first source in response to the voltage of the I/O terminal being above the voltage range.

19. The system of claim 16, wherein a bias voltage of the bias terminal is based on a first resistance of the one or more primary resistor ladder circuitries, a third resistance of the second secondary resistor ladder circuitry, and a voltage value of the second source in response to the voltage of the I/O terminal being below the voltage range.

20. The system of claim 16, wherein the voltage range is between −0.3 volts and 1.8 volts.
